(19) United States
(12) Patent Application Publication
(10) Pub. No.: US 2014/0182222 A1
(43) Pub. Date: Jul. 3, 2014

(54) Photovoltaic Arrays, Methods and Kits Therefor

(71) Applicant: Certainteed Corporation, Valley Forge, PA (US)

(72) Inventors: Husnu M. Kalkanoglu, Swarthmore, PA (US); Joseph J. Quaranta, Yardley, PA (US); Stephen A. Koch, Collegeville, PA (US)

(73) Assignee: CERTAINTEED CORPORATION, Valley Forge, PA (US)

(21) Appl. No.: 14/196,452

(22) Filed: Mar. 4, 2014

Related U.S. Application Data
(62) Division of application No. 12/946,452, filed on Nov. 15, 2010.
(60) Provisional application No. 61/261,638, filed on Nov. 16, 2009.

(51) Int. Cl. H01L 31/048; H01L 31/05

(52) U.S. Cl. CPC H01L 31/0482; H01L 31/0504
USPC 52/173.3; 136/251

(57) ABSTRACT

The present invention relates generally to the photovoltaic generation of electrical energy. The present invention relates more particularly to photovoltaic arrays for use in photovoltaically generating electrical energy. One aspect of the invention is a photovoltaic array including a first photovoltaic module and a second photovoltaic module, each comprising a set of linearly arranged features extending from its lateral edge, and an electrical element on its surface, wherein the lateral distance between the electrical element and the center of the linearly-arranged feature closest to the lateral edge is different in the first photovoltaic module than in the second.

### CROSS-REFERENCE TO RELATED APPLICATIONS

This application is a divisional of U.S. patent application Ser. No. 12/946,452, filed Nov. 15, 2010, which claims priority under 35 U.S.C. §119(e) to U.S. Provisional Patent Application Ser. No. 61/261,638, filed Nov. 16, 2009, each of which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic roofing products for use in photovoltaically generating electrical energy.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as system performance has improved. They can be used, for example, to provide at least a significant fraction of the electrical energy needed for a building's overall function; or they can be used to power one or more particular devices, such as exterior lighting systems and well pumps.

Arrays of photovoltaic modules are being developed for disposal on a roof; they can be installed over an existing roof to provide photovoltaic power generation. Moreover, research and development attention has turned toward integrating photovoltaic cells with roofing products such as shingles, shakes or tiles. A plurality of photovoltaic roofing elements (i.e., photovoltaic modules formed from photovoltaic media integrated with a roofing product) can be installed together on a roof, and electrically interconnected to form a photovoltaic roofing system that provides both environmental protection and photovoltaic power generation.

When identical strip-shaped photovoltaic modules are installed on a roof, electrical connections between modules are made to connect the array and build voltage in the array. In cases where the photovoltaic modules have multiple individual photovoltaic elements, or other features arranged (e.g., linearly) to emulate a shingle-like or tile-like effect, and adjacent courses of photovoltaic modules up and down the roof are laterally offset one from another, electrical elements such as junction boxes for the wiring and connection at one end of the array are also laterally offset one from another. Containment of the wiring connections requires a relatively wide raceway to protect the wiring system from the environment. Such wide raceways can require a relatively large amount of material, and can cause undesirable aesthetic appearance.

There remains a need for photovoltaic products that address one or more of these deficiencies.

### SUMMARY OF THE INVENTION

Various aspects of the present invention are directed to roofing-integrated photovoltaic arrays and configurations for efficiently covering and closing electrical connection systems of the arrays with economical use of materials while providing a streamlined aesthetic appearance and minimizing or avoiding penetrations of the roof deck. In certain aspects, photovoltaic arrays of the present invention include matched sets of photovoltaic modules, the modules having electrical elements (i.e., any feature protruding from or formed in the face of module and used in electrical connections, e.g., connectors, junction boxes, sockets) located such that when the modules are arranged in a laterally offset arrangement of courses in a photovoltaic array, the electrical connection points align spatially, thus minimizing the area of exposed wiring system in need of covering by a wiring raceway cover or conduit.

Accordingly, one aspect of the invention is a photovoltaic array comprising a first photovoltaic module comprising
a lateral edge,
a set of linearly arranged features extending from that lateral edge, and
an electrical element on the surface of the photovoltaic module; and
a second photovoltaic module disposed substantially parallel to and vertically and laterally offset with respect to the first photovoltaic module, the second photovoltaic module comprising
a lateral edge oriented facing substantially the same direction as the lateral edge of the first photovoltaic module,
a set of linearly arranged features extending from that lateral edge, and
an electrical element on the surface of the photovoltaic module;
   wherein the lateral distance between the electrical element and the center of the linearly-arranged feature closest to the lateral edge is different in the first photovoltaic module than in the second.

Another aspect of the invention is a photovoltaic array (for example, as described above) comprising a first photovoltaic module comprising
a lateral edge,
a set of linearly arranged features extending from that lateral edge, and
an electrical element on the surface of the photovoltaic module; and
a second photovoltaic module disposed substantially parallel to and vertically and laterally offset with respect to the first photovoltaic module, the second photovoltaic module comprising
a lateral edge oriented facing substantially the same direction as the lateral edge of the first photovoltaic module,
a set of linearly arranged features extending from that lateral edge, and
an electrical element on the surface of the photovoltaic module;
   wherein the lateral distance between the electrical element and the lateral edge is substantially the same in the first photovoltaic module as in the second.

Another aspect of the invention is a photovoltaic array (for example, as described above) comprising
a first photovoltaic module comprising
   a first lateral edge and a second lateral edge,
   a set of linearly arranged features extending between the first lateral edge and the second lateral edge, and
   an electrical element on the surface of the photovoltaic module; and
a second photovoltaic module disposed substantially parallel to and vertically and laterally offset with respect to the first photovoltaic module, the second photovoltaic module comprising
   a first lateral edge oriented facing substantially the same direction as the first lateral edge of the first photovoltaic module, and a second lateral edge oriented facing substantially the same direction as the second lateral edge of the first photovoltaic module;
   a set of linearly arranged features extending between the first lateral edge and the second lateral edge, and
   an electrical element on the surface of the photovoltaic module;
      wherein the lateral distance between the electrical element and the center of the linearly-arranged feature closest to the first lateral edge is different in the first photovoltaic module than in the second, and wherein the sum of the distance between the electrical element and the first lateral edge of the first photovoltaic module and the electrical element and the second lateral edge of the second photovoltaic module is substantially the same as the lateral offset distance between the first photovoltaic module and the second photovoltaic module. In certain embodiments, the lateral distance between the electrical element of the first photovoltaic module and the first lateral edge of the first photovoltaic module is substantially the same as the lateral distance between the electrical element of the second photovoltaic module and the second lateral edge of the second photovoltaic module.

Another aspect of the invention is a photovoltaic array as described above, in which electrical elements of vertically-disposed courses of photovoltaic modules are substantially laterally aligned with one another.

Another aspect of the invention is a photovoltaic array as described above, including a cover (e.g., to provide environmental protection and/or camouflaging of the electrical elements and any wiring running therebetween, e.g., a raceway cover or conduit) disposed over the substantially laterally-aligned electrical elements.

Another aspect of the invention is a kit for the provision of a photovoltaic array (for example, as described above), the kit comprising:
one or more first photovoltaic modules, each comprising
   a lateral edge,
   a set of linearly arranged features extending from that lateral edge, and
   an electrical element on the surface of the photovoltaic module; and
one or more second photovoltaic modules, each comprising
   a lateral edge to be installed facing substantially the same direction as the lateral edge of the first photovoltaic module,
   a set of linearly arranged features extending from that lateral edge, and
   an electrical element on the surface of the photovoltaic module;
      wherein the lateral distance between the electrical element and the center of the linearly-arranged feature closest to the lateral edge is different in the first photovoltaic module than in the second.

Another aspect of the invention is a kit for the provision of a photovoltaic array (for example, as described above), the kit comprising:
one or more first photovoltaic modules, each comprising
   a lateral edge,
   a set of linearly arranged features extending from that lateral edge, and
   an electrical element on the surface of the photovoltaic module; and
one or more second photovoltaic modules, each comprising
   a lateral edge oriented to be installed facing substantially the same direction as the lateral edge of the first photovoltaic module,
   a set of linearly arranged features extending from that lateral edge, and
   an electrical element on the surface of the photovoltaic module;
      wherein the lateral distance between the electrical element and the center of the linearly-arranged feature closest to the lateral edge is different in the first photovoltaic module than in the second, and the lateral distance between the electrical element and the lateral edge is substantially the same in the first photovoltaic module as in the second.

Another aspect of the invention is a kit for the provision of a photovoltaic array (for example, as described above) comprising
one or more first photovoltaic modules, each comprising
   a first lateral edge and a second lateral edge,
   a set of linearly arranged features extending between the first lateral edge and the second lateral edge, and
   an electrical element on the surface of the photovoltaic module; and
one or more second photovoltaic modules, each comprising
   a first lateral edge to be installed facing substantially the same direction as the first lateral edge of the first photovoltaic module, and a second lateral edge to be installed facing substantially the same direction as the second lateral edge of the first photovoltaic module;
   a set of linearly arranged features extending between the first lateral edge and the second lateral edge, and
   an electrical element on the surface of the photovoltaic module;
      wherein the lateral distance between the electrical element and the center of the linearly-arranged feature closest to the first lateral edge is different in the first photovoltaic module than in the second, and wherein the sum of the distance between the electrical element and the first lateral edge of the first photovoltaic module and the electrical element and the second lateral edge of the second photovoltaic module is substantially the same as the lateral offset distance between the first photovoltaic module and the second photovoltaic module. In certain embodiments, the lateral distance between the electrical element of the first photovoltaic module and the first lateral edge of the first photovoltaic module is substantially the same as the lateral distance between the electrical element of the second photovoltaic module and the second lateral edge of the second photovoltaic module.

Another aspect of the invention is a kit as described above, further including a cover (e.g., a raceway or conduit) to be disposed over the electrical elements when disposed in an array in substantial lateral alignment.

Notably, in the arrays and kits according to various aspects of the invention, the first photovoltaic module(s) and the second photovoltaic module(s) are not substantially identical to one another, and simply installed on the roof rotated 180 from one another. Rather, the first photovoltaic module(s) and the second photovoltaic module(s) differ in the placement of the electrical element with respect to the overall module.

One benefit of certain embodiments of the invention is the provision of a system including two different types of photovoltaic modules with electrical elements differently-disposed on each type of module, such that when the modules are arranged in a laterally-offset array, the electrical elements are substantially linearly aligned. Another benefit of certain embodiments of the invention is the provision of a system including wiring raceway or conduit for wire management that need not span laterally offset electrical elements at an edge of an array of strip-shaped photovoltaic modules. Accordingly, the raceway or conduit system can be relatively compact in width, and can make relatively economic use of electrical wiring materials. Other benefits and advantages of the present invention will be readily understood upon a reading of the following brief descriptions of the drawing figures, the detailed descriptions of the preferred embodiments of the invention.

The invention will be further described with reference to embodiments depicted the appended figures. It will be appreciated that elements in the figures are illustrated for simplicity and clarity and have not necessarily been drawn to scale. For example, the dimensions of some of the elements in the figures may be exaggerated relative to other elements to help to improve understanding of embodiments of the invention.

### BRIEF DESCRIPTION OF THE DRAWINGS

The accompanying drawings are not necessarily to scale, and sizes of various elements can be distorted for clarity.

FIG. 1 is a top schematic view of a racked array of photovoltaic modules;

FIG. 2 is a top schematic view and an edge schematic view of a racked array of photovoltaic modules fitted with a cover for the electrical elements protruding therefrom;

FIG. 3 is a top schematic view of a pair of photovoltaic modules and a photovoltaic array according to one embodiment of the invention;

FIG. 4 is a top schematic view of the photovoltaic array of FIG. 3 installed with a cover;

FIG. 5 is a top schematic view of another photovoltaic array according to another embodiment of the invention;

FIG. 6 is a top schematic view pair of photovoltaic modules and a photovoltaic array according to another embodiment of the invention;

FIG. 7 is a top schematic view and edge schematic view of the photovoltaic array of FIG. 6 installed with a cover;

FIG. 8 is a top schematic view of a photovoltaic array according to another embodiment of the invention;

FIGS. 9 and 10 are schematic views of arrangement of wiring components in photovoltaic modules suitable for use in practicing certain aspects of the invention;

FIG. 11 is a schematic view of an array of photovoltaic roofing elements according to one embodiment of the invention; and

FIGS. 12-15 are pictures of examples of a photovoltaic arrays installed on a roof deck according to various embodiments of the invention.

### DETAILED DESCRIPTION OF THE INVENTION

The field of roofing-integrated photovoltaic products has been advancing in recent years. U.S. Pat. No. 5,575,861 and U.S. Pat. No. 5,437,735; and U.S. Patent Application Publications nos. 2009/0159118 and 2009/0178350 each of which is hereby incorporated herein by reference in its entirety, disclose roofing products and systems where a roof is equipped with photovoltaic capabilities while emulating the appearance of a shingled roof.

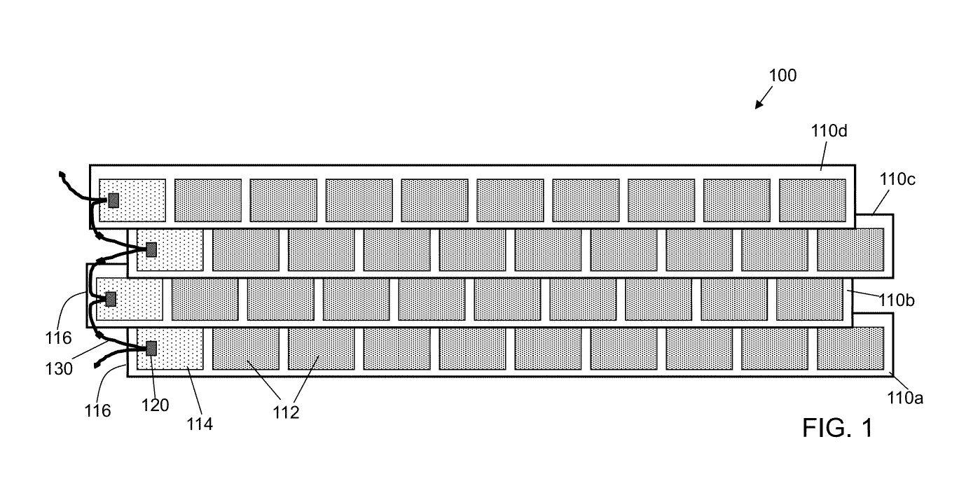

When identical strip-shaped photovoltaic modules are installed on a roof in an array, electrical interconnections between modules are made to build voltage in the array and to provide a route for the generated electrical power to be removed from the roof to a larger electrical system. To avoid penetrations through the roof, electrical elements such as junction boxes and wiring components can be provided near an end of each module. When modules have photovoltaic elements or other features arranged to emulate a shingle-like or tile-like effect, and adjacent courses of photovoltaic modules are laterally offset one from another, the electrical junction boxes for the wiring and connection at one end of the array are also laterally offset one from another. A so-called “racked” installation keeps the module electrical elements localized near an edge of the portion of the array, traversing up the roof near the side of the photovoltaic zone. FIG. 1 is a top schematic view of a racked array 100 of identical strip-shaped photovoltaic modules 110, each of which includes an electrical feature 120, and a plurality of individual photovoltaic elements 112 (here, individual photovoltaic cells, interconnected with one another and to the electrical element by wiring internal to the module). The electrical elements 120 (here, junction boxes for the connection of interconnecting wires 130) are disposed on dummy cells 114 disposed at the end of the modules. The dummy cells do not have active photovoltaic material, but rather have visual appearance complementary to the active photovoltaic cells, so as to provide added aesthetic benefit. The modules of the array are substantially identical with respect to the placement of the electrical elements 112 with respect to the lateral edges 116 of the modules. The photovoltaic modules are configured in a racked arrangement, with the first course module 110a in place, a second course module 110b is disposed superadjacent to and laterally offset from the first course module 110a, so that the photovoltaic elements (or other features) of the two courses take on the horizontally-offset appearance typical to a shingled or tiled roof. Continuing up the array, a third course module 110c is disposed superadjacent and laterally offset from the second course module 110b such that it is in lateral alignment with the first course module 110a; and a fourth course module is disposed superadjacent to and laterally offset from the third course module 110c such that it is in lateral alignment with the second course module 110b. In an actual installation, additional photovoltaic modules may be disposed to the right or to the left of the portion of the array, or above or below the portion of the array (not shown). In such cases, dummy portions of inactive material 114 can be arranged so that the raceway covers to not interfere with active areas. Alternatively, with the offset of the modules, more conventional shingles may be interleaved into the module arrangement to effectively merge the photovoltaic array with the non-active shingle portions of the roof and integrate the photovoltaic portion with the remainder of the roof (also not shown).

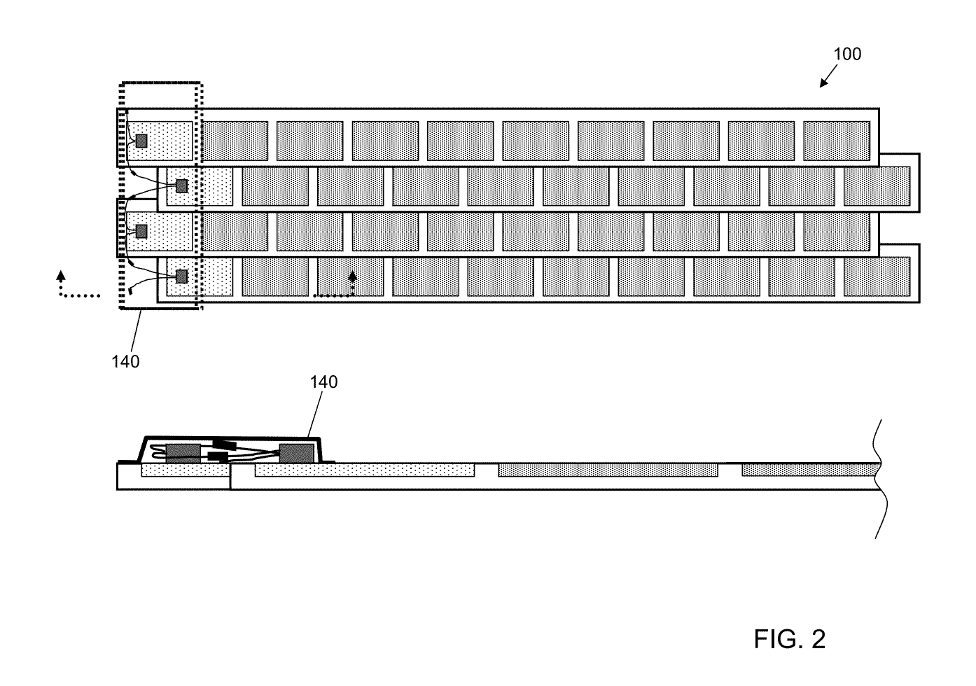

Containment of the electrical system is often desired to protect it from the environment, protect against damage through physical activities on the roof and provide a cleaner aesthetic appearance than that of a collection of visible electrical wiring connecting the electrical elements. When the photovoltaic modules are laterally-offset, such as in the racked configuration, the electrical elements are also laterally offset from one another. Accordingly, a covering for them would require a relatively wide raceway (i.e., having sufficient width to cover the laterally-offset electrical elements between immediately adjacent courses traversing up the array). For example, FIG. 2 shows a top schematic view and a side partial schematic view of the array 100 of FIG. 1 with a raceway cover 140 (shown in dotted outline in the top schematic view) disposed thereon. The side schematic view of FIG. 2 shows an edge view along the direction of the arrows provided in the top schematic view. The lower edge of the first course module is visible as is the lower edge of the laterally offset second course module. The raceway cover has sufficient width to contain the junction boxes, electrical wiring and connections for the set of modules. Notably, in the embodiment of FIG. 2, the raceway cover needs to be relatively wide, so as to cover the laterally-offset electrical elements of the various courses. Use of such wide raceways can be disadvantageous. For example, wider raceways increase material and installation costs. Moreover, wider raceways can provide a relatively large aesthetic disruption to the roof.

Accordingly, one aspect of the invention is a photovoltaic array including: first photovoltaic module including a lateral edge, a set of linearly arranged features extending from that lateral edge, and an electrical element on the surface of the photovoltaic module; and a second photovoltaic module disposed substantially parallel to and laterally offset with respect to the first photovoltaic module, the second photovoltaic module comprising a lateral edge oriented facing substantially the same direction as the lateral edge of the first photovoltaic module, a set of linearly arranged features extending from that lateral edge, and an electrical element on the surface of the photovoltaic module. The lateral distance between the electrical element and the center of the linearly-arranged feature closest to the lateral edge is different in the first photovoltaic module than in the second. In such embodiments, the photovoltaic modules of the array are not substantially identical with respect to the placement of the electrical elements with respect to the lateral edges the modules.

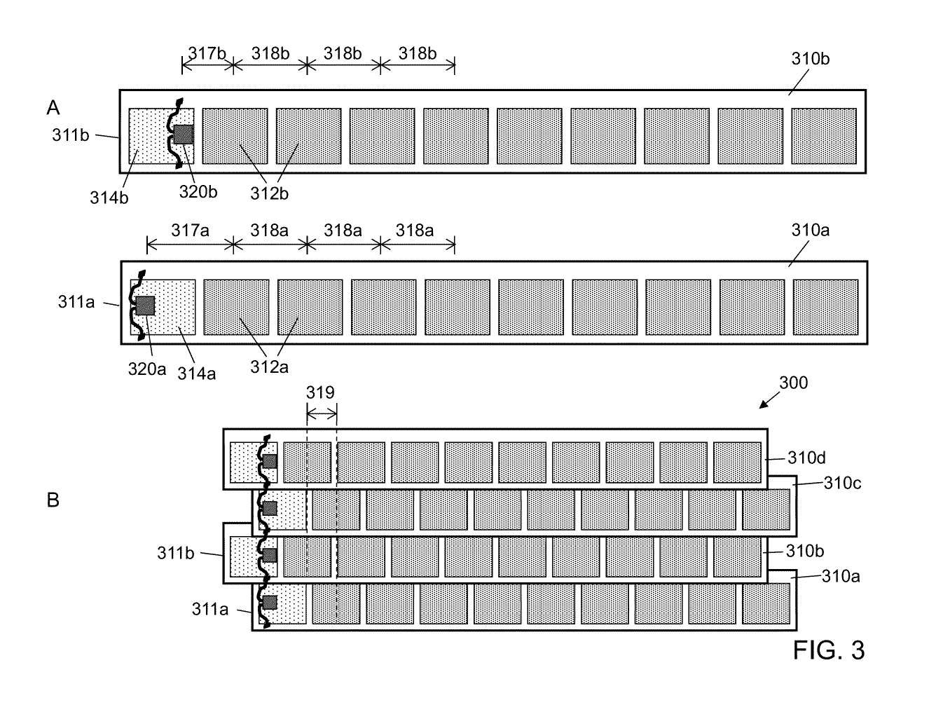

An example of such a photovoltaic array is shown in top view in FIG. 3. FIG. 3A shows two different types of photovoltaic modules 310a and 310b, each of which includes lateral edges 311a and 311b facing to the left of the page; a set of linearly arranged features 312a and 312b (here, individual photovoltaic elements) extending from the lateral edges; and an electrical element 320a and 320b (here, junction boxes) disposed on the surfaces of the photovoltaic modules. Each photovoltaic module of FIG. 3A also includes dummy cell 314a and 314b, on which the electrical elements are disposed. In FIG. 3B, the photovoltaic modules are arranged in an array 300. Second photovoltaic module 310b is disposed substantially parallel to and laterally offset (by distance 319) with respect to the first photovoltaic module 310a, and with its lateral edge 311b oriented facing substantially the same direction as the lateral edge 311a of the first photovoltaic module. The photovoltaic modules can be arranged vertically up the array in an offset fashion, for example, as is conventional in the installation of roofing materials. The photovoltaic modules can, for example, be arranged so as to partially overlap vertically, as is conventional in the installation of roofing materials.

The two configurations of photovoltaic module differ in the lateral placement of the electrical element with respect to the center of the linearly-arranged feature closest to the lateral edge. Distances with respect to electrical elements can be measured, for example, from the center of the electrical elements. Certain distances are marked in FIG. 3. The lateral distance between the electrical element and the center of the linearly-arranged feature closest to the lateral edge 311a for the first photovoltaic module is marked with arrow 317a, and the lateral distance between the electrical element and the center of the linearly-arranged feature closest to the lateral edge for the second photovoltaic module is marked with arrow 317b. Lateral distances between the centers of adjacent linearly arranged features are marked in FIG. 3 as arrows 318a and 318b. Accordingly, according to an aspect of the invention distance 317a differs from distance 317b (e.g., in FIG. 3, distance 317a is greater than distance 317b).

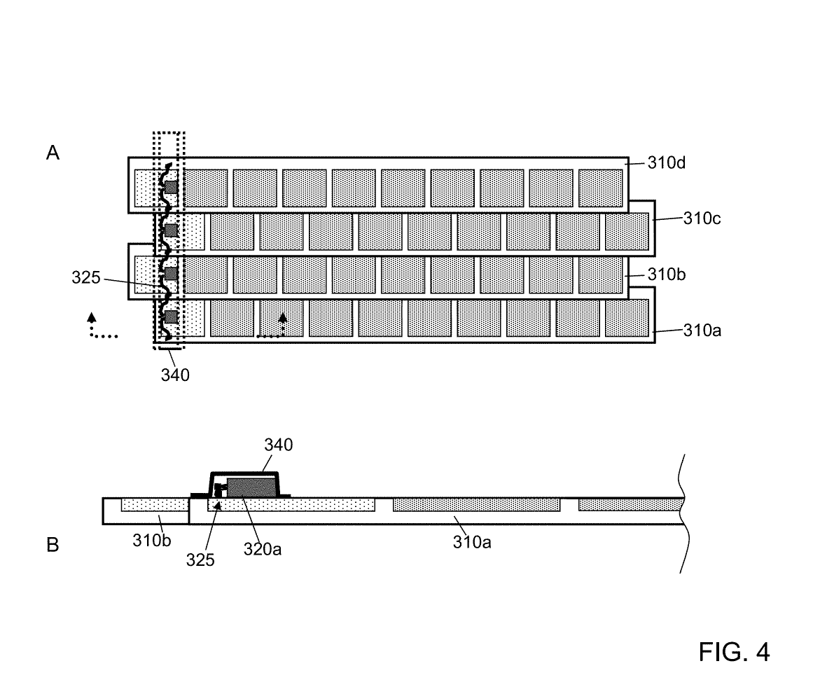

In the embodiment of FIG. 3, for example, the two photovoltaic module configurations differ in the placement of the junction box within the dummy cell. The first module has the junction box farther from the center of the edge-most photovoltaic element of the module, here, toward the end of the dummy cell nearer the lateral edge of the module. A second module has the junction box laterally offset within the area of the dummy cell relative to the location of the junction box of the first module, i.e., closer to the center of the edge-most photovoltaic element of the module, here toward the end of the dummy cell nearer the edge-most photovoltaic element of the module. The lateral offset can correspond, as shown here, to the spatial lateral offset of the modules when they are installed in an array such that the junction boxes align substantially laterally, as shown in FIG. 3B. The substantially lateral alignment of the junction boxes allows relatively short lengths of wiring to be used in connecting modules in adjacent courses, and the containment of the wiring and junction boxes by a relatively narrow electrical raceway cover as shown in FIG. 4. The electrical raceway containing the wiring and junction boxes of the array is shown in a bottom edge view in FIG. 4B taken along the direction of the arrows noted in FIG. 4A. Notably, the raceway cover is much narrower than that possible with identically-configured modules. The first photovoltaic module 310a can be seen with its junction box 320a and wiring within the raceway. The second course module 310b with the laterally offset junction box location can be seen extending leftwardly beyond the end of the first course module, its junction box and electrical wiring 325 being contained within the electrical raceway cover (i.e., disposed behind junction box 320a in this view). The electrical raceway cover 340 does not cover or obscure any of the active area of the modules of the photovoltaic array. Accordingly, using different types of modules to allow for substantially laterally aligned electrical connections can allow for efficient use of wiring materials in connection of adjacent courses of photovoltaic modules; and can allow for relatively narrow raceway or conduit covers to be used.

The lateral offset distance between the photovoltaic modules is the lateral distance between the linearly arranged features of the photovoltaic modules. For example, in FIG. 3, the lateral offset distance is measured between the centers of the linearly-arranged features, and is marked with arrow 319. In one embodiment of the invention, the lateral offset distance is substantially the same as the difference between the lateral distance from the electrical element to the center of the linearly-arranged feature closest to the lateral edge in the first photovoltaic module and the lateral distance from the electrical element to the center of the linearly-arranged feature closest to the lateral edge in the second photovoltaic module. That is, in the embodiment of FIG. 3, the difference between distance 317a and distance 317b is substantially the same as distance 319.

In one embodiment of the invention, the difference between the lateral distance from the electrical element to the center of the linearly-arranged feature closest to the lateral edge in the first photovoltaic module and the lateral distance from the electrical element to the center of the linearly-arranged feature closest to the lateral edge in the second photovoltaic module is substantially the same as a positive integral fraction of the average lateral distance between the centers of adjacent linearly arranged features. A positive integral fraction, as used herein, is the inverse of a positive integer. Examples of positive integral fractions are 1/1, ½, ⅓ and ¼. For example, in the embodiment of FIG. 3, the difference between distance 317a and distance 317b is substantially the same as the half of the average of the distances 318a. The integer denominator of the integral fraction can be the number of courses in the repeat unit of the racked installation (in this example, 2).

Of course, additional photovoltaic modules can be disposed vertically up the array. In the example of FIGS. 3 and 4, a third photovoltaic module 310c is disposed up the roof from second photovoltaic module 310b, and is substantially laterally aligned with first photovoltaic module 310a; and a fourth photovoltaic module 310d is disposed up the roof from third photovoltaic module 310c, and is substantially laterally aligned with second photovoltaic module 310b. The pattern can be repeated up the roof to provide a desired sized array.

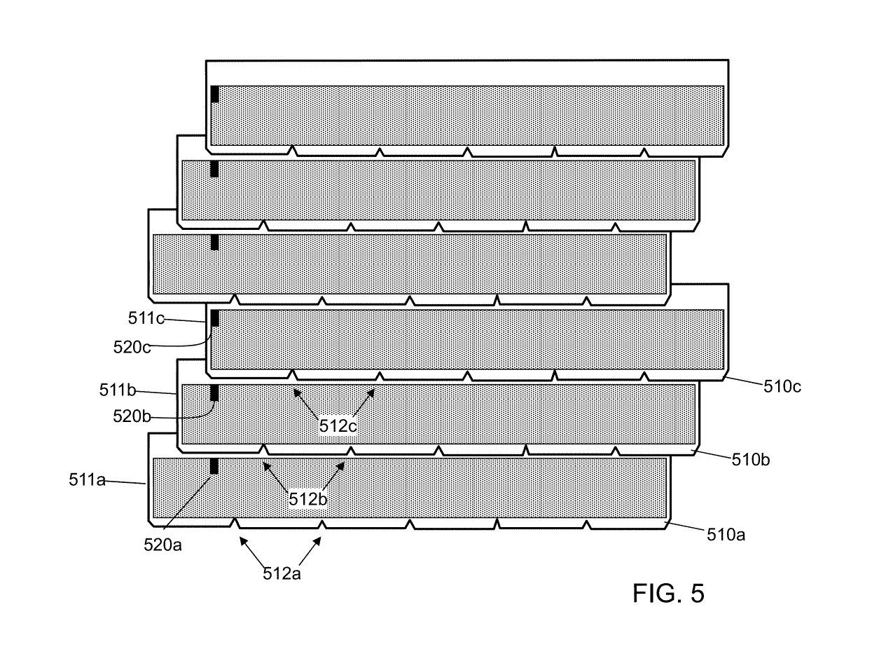

In the example of FIGS. 3 and 4, the pattern repeats after two photovoltaic modules. Of course, other schemes can be used. For example, in the photovoltaic array shown in top schematic view in FIG. 5, a three module repeat unit can be used. The array includes a first photovoltaic module 510a and a second photovoltaic module 510b, and a third photovoltaic module 510c, each of which includes lateral edges 511a, 511b and 511c facing to the left of the page; a set of linearly arranged features 512a, 512b and 512c (here, notch-shaped features in the structures of the photovoltaic modules provided as shingle-shaped photovoltaic roofing elements) extending from the lateral edges; and an electrical element 520a, 520b and 520c (here, wiring connectors) disposed on the surfaces of the photovoltaic modules. In this embodiment, the lateral distance between the electrical element and the center of the linearly-arranged feature closest to the lateral edge of the photovoltaic module is different for each of photovoltaic modules 510a, 510b and 510c. The photovoltaic modules are arranged vertically up the array in an offset fashion, for example, as is conventional in the installation of roofing materials. Second photovoltaic module 510b is disposed substantially parallel to and laterally offset with respect to the first photovoltaic module 510a, and with its lateral edge 511b oriented facing substantially the same direction as the lateral edge 511a of the first photovoltaic module; and third photovoltaic module 510c is disposed substantially parallel to and laterally offset with respect to the second photovoltaic module 510b, and with its lateral edge 511c oriented facing substantially the same direction as the lateral edge 511b of the second photovoltaic module. The photovoltaic modules are arranged so as to partially overlap vertically, as is conventional in the installation of roofing materials. Notably, the electrical connectors are substantially laterally aligned with one another, which can provide the advantages described herein.

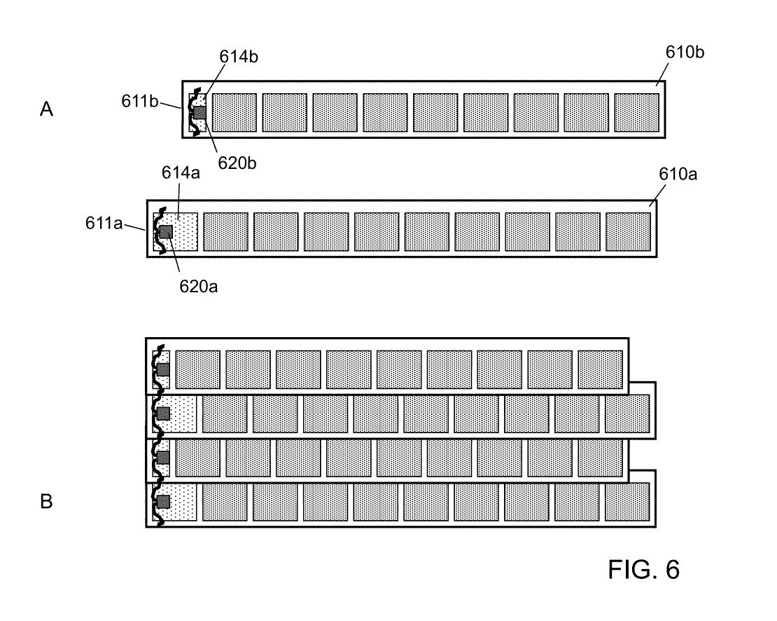

In certain embodiments of the invention, the lateral distance between the electrical element and the lateral edge is substantially the same in the first photovoltaic module as in the second. This configuration can allow for the lateral edges of the photovoltaic modules to be substantially aligned, which can be desirable, for example, at the edge of the roof, or to provide a “squared-off” appearance. An example is shown in top schematic view in FIG. 6. As shown in FIG. 6A, in photovoltaic modules 610a and 610b, the lateral distance between the electrical element 620a and the lateral edge 611a of the first photovoltaic module is about the same as the lateral distance between the electrical element 620b and the lateral edge 611b of the second photovoltaic module. As described above, however, the lateral distance between the electrical element and the center of the linearly-arranged feature closest to the lateral edge is different in the first photovoltaic module than in the second. In this embodiment, the dummy cell 614a of the first photovoltaic module is about the same size as the linearly-arranged photovoltaic cells of the module, while the dummy cell 614b of the second photovoltaic module is much shorter. Accordingly, when disposed in an array as shown in FIG. 6B, the linearly arranged features can be disposed in a laterally-offset configuration (e.g., to emulate the appearance of shingles or tiles), but the lateral edges can be aligned, with the electrical features and any wiring interconnecting them also substantially laterally aligned. The alignment of the electrical connection system allows the use of a compact streamlined electrical raceway cover 640 as shown in FIGS. 7A and 7B. The raceway does not interfere with the active area of the photovoltaic cells. A single compact raceway can provide wire management for the portion of the array of FIG. 7A. The modules with aligned electrical connections allow for efficient use of wiring materials in connection of adjacent courses of photovoltaic modules. In the embodiment shown in FIG. 7A, the left end of the array is horizontally aligned with the raceway cover. The raceway may include structures for flashing into a field of shingles to the left of the array as disclosed, for example, in U.S. Patent Application Publication no. 2010/0242381, which is hereby incorporated by reference herein in its entirety. Other array portions or fields of shingles could be installed above or below, or to the right or left of the array portion (e.g., in a dovetailed fashion). Alternatively, the array may terminate at an edge of the roof

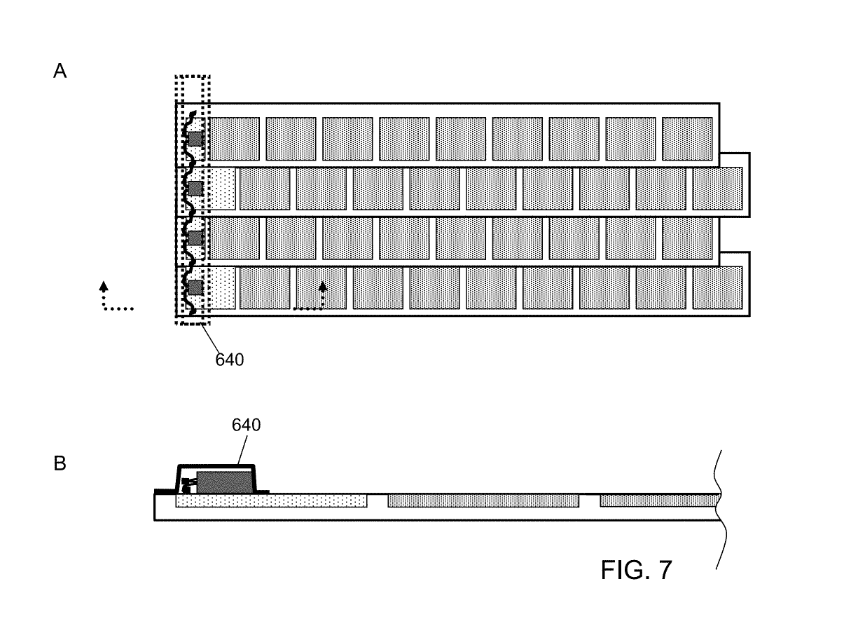

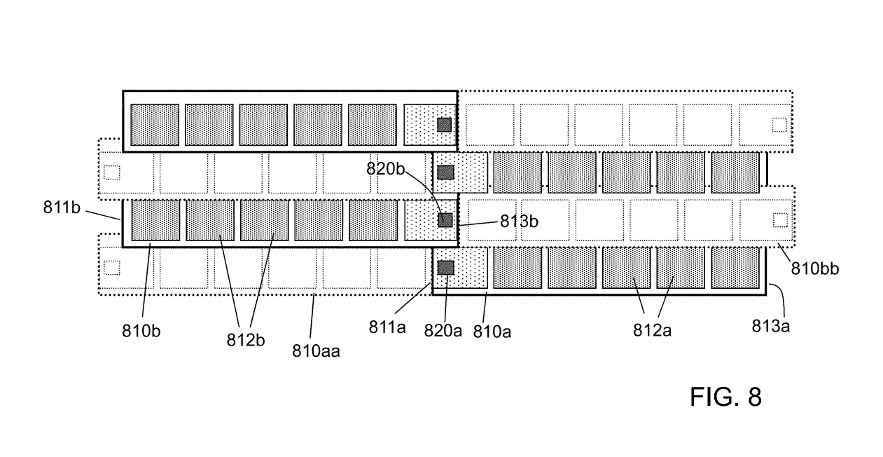

In another embodiment of the invention, the lateral distance between the electrical element of the first photovoltaic module and a first lateral edge of the first photovoltaic module is substantially the same as the lateral distance between the electrical element of the second photovoltaic module and a second, differently facing (e.g., oppositely facing) lateral edge of the second photovoltaic module. Such an embodiment is shown in top schematic view in FIG. 8. In the array of FIG. 8, the electrical features are disposed at opposite ends of vertically alternating photovoltaic modules (e.g., with the modules of the first and third courses having electrical features at the left side of the array, and the modules of the second and fourth courses having connector systems at the right side of the array). Accordingly, the embodiment of FIG. 8 includes a first photovoltaic module 810a including a first lateral edge 811a and an opposite-facing second lateral edge 813a, a set of linearly arranged features 812a extending between the first lateral edge and the second lateral edge, and an electrical element 820a on the surface of the first photovoltaic module; and a second photovoltaic module 810b disposed substantially parallel to and vertically and laterally offset with respect to the first photovoltaic module, the second photovoltaic module including a first lateral edge 811b oriented facing substantially the same direction as the first lateral edge 811a of the first photovoltaic module 810a, and a second lateral edge 813b oriented facing substantially the same direction as the second lateral edge 813a of the first photovoltaic module 810a; a set of linearly arranged features 812b extending between the first lateral edge and the second lateral edge, and an electrical element 820b on the surface of the second photovoltaic module. As described above, the lateral distance between the electrical element and the center of the linearly-arranged feature closest to the first lateral edge is different in the first photovoltaic module than in the second. Indeed, in this example, the difference in distances is fairly drastic, as the electrical element is disposed proximal to the first lateral edge in the first photovoltaic module, and distal to the first lateral edge in the second photovoltaic module. Moreover, the sum of the distance between the electrical element and the first lateral edge of the first photovoltaic module and the electrical element and the second lateral edge of the second photovoltaic module is substantially the same as the lateral offset distance between the first photovoltaic module and the second photovoltaic module. The array also includes photovoltaic modules 810aa (configured similarly to, but disposed in substantial lateral overlap with photovoltaic modules 810b) and photovoltaic modules 810bb (configured similarly to, but disposed in substantial lateral overlap with photovoltaic modules 810a.) Additional photovoltaic modules can be disposed up the roof in a dovetailed fashion, such that the electrical elements and any wiring can be contained by a common raceway cover. Accordingly, a single narrow raceway can be used to contain these electrical elements. In certain embodiments, the lateral distance between the electrical element of the first photovoltaic module and the first lateral edge of the first photovoltaic module is substantially the same as the lateral distance between the electrical element of the second photovoltaic module and the second lateral edge of the second photovoltaic module.

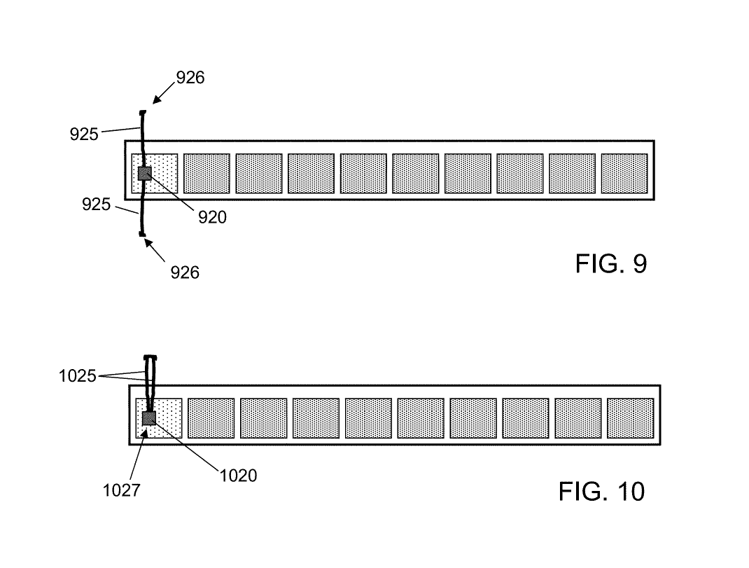

Wiring can be used to interconnect the electrical elements of an array, for example, as shown in FIGS. 1, 3, 4, 6 and 7. FIGS. 9 and 10 are partial top schematic views of photovoltaic modules having alternative arrangement of wiring in the vicinity of the electrical element. In the embodiment of FIG. 9, wiring components 925 (terminated in connectors 926) for interconnecting the module to other parts of the array extend from the top edge and the bottom of the electrical element 920. In the embodiment of FIG. 10, wires 1025 exit the top edge of the electrical element to extend toward a next such module in an array, and a connection socket 1027 is provided in the lower portion of the junction box to receive the connections from another module of the array, or in some cases a jumper connector to terminate an array portion. The wiring arrangements shown in FIGS. 9 and 10 are examples of approaches to making the wiring compact to allow for streamlined compact electrical raceway coverings that do not detract from the aesthetics of the roof equipped with an integrated photovoltaic array. It will be understood that other connectors and wiring schemes will be within the ambit of those skilled in the art.

In certain embodiments described above, dummy cells are provided for aesthetic effect. As the person of skill in the art will recognize, in other embodiments no dummy cell is provided at the edge of each module; rather, the edge merely presents the base material of the module (e.g., roofing substrate or encapsulant material).

Many of the embodiments described above included individual photovoltaic elements as the linearly-arranged feature. The individual photovoltaic elements can be, for example, individual photovoltaic cells, or wired-together arrays of photovoltaic cells. In other embodiments, for example as shown in FIG. 5, the linearly arranged features are geometrical shapes formed in the photovoltaic module, such as features that approximate the look of shingles or tiles, or provide some other aesthetic benefit.

The cover can be provided in a number of architectures, as would be apparent to the person of skill in the art. The cover can be provided, for example, as a conduit, or a raceway cover. The cover can be formed from a variety of materials, such as plastic or metal. In certain embodiments, the cover does not substantially shield the active portions of the photovoltaic module from incoming solar radiation. For example, the cover can be disposed along any dummy cells or other inactive portions of the photovoltaic modules. The cover can be attached to the roof in any desirable manner. For example, in the embodiment of FIG. 4, a flange is provided for attachment of the raceway cover to the roof. Attachment can be made, for example, via a mechanical fastener such as a nail, staple or screw, and/or using an adhesive. could be used to attach the cover. In certain embodiments where a metallic or metal cover is used the metallic and/or electrically active parts or components of the array can be grounded.

The photovoltaic modules themselves can be provided in a variety of architectures. For example, the photovoltaic modules can be provided as encapsulated photovoltaic modules, in which photovoltaic cells are encapsulated between various layers of material (e.g., as a laminate). For example, a photovoltaic laminate can include a top laminate layer at its top surface, and a bottom laminate layer at its bottom surface. The top laminate layer material can, for example, provide environmental protection to the underlying photovoltaic cells, and any other underlying layers. Examples of suitable materials for the top layer material include fluoropolymers, for example ETFE (“TEFZEL”, or NORTON ETFE), PFE, FEP, PVF (“TEDLAR”), PCTFE or PVDF. The top laminate layer material can alternatively be, for example, a glass sheet, or a non-fluorinated polymeric material (e.g., polypropylene or acrylic). The bottom laminate layer material can be, for example, a fluoropolymer, for example ETFE (“TEFZEL”, or NORTON ETFE), PFE, FEP, PVDF or PVF (“TEDLAR”). The bottom laminate layer material can alternatively be, for example, a polymeric material (e.g., polyolefin such as polypropylene, polyester such as PET); or a metallic material (e.g., steel or aluminum sheet).

As the person of skill in the art will appreciate, a photovoltaic laminate can include other layers interspersed between the top laminate layer and the bottom laminate layer. For example, a photovoltaic laminate can include structural elements (e.g., a reinforcing layer of glass, metal, glass or polymer fibers, a rigid film, or a flexible film); adhesive layers (e.g., EVA to adhere other layers together); mounting structures (e.g., clips, holes, or tabs); one or more electrical components (e.g., electrodes, electrical connectors; optionally connectorized electrical wires or cables) for electrically interconnecting the photovoltaic cell(s) of the encapsulated photovoltaic module with an electrical system. As described in more detail below, any interconnections between photovoltaic cells, and any bypass diodes can be included within the laminate.

The photovoltaic module can include at least one antireflection coating, for example as the top layer material in an encapsulated photovoltaic element, or disposed between the top layer material and the photovoltaic cells. The photovoltaic module can also be made colored, textured, or patterned, for example by using colored, textured or patterned layers in the construction of the photovoltaic element. Methods for adjusting the appearance of photovoltaic elements are described, for example, in U.S. Patent Application Publications nos. 2010/0282318, 2008/0006323, 2008/0271773, 2009/0000221, 2009/0133738 and 2009/0133739, each of which is hereby incorporated herein by reference.

Suitable photovoltaic modules can be obtained, for example, from China Electric Equipment Group of Nanjing, China, as well as from several domestic suppliers such as Uni-Solar Ovonic, Sharp, Shell Solar, BP Solar, USFC, FirstSolar, Ascent Solar, General Electric, Schott Solar, Evergreen Solar and Global Solar. Moreover, the person of skill in the art can fabricate photovoltaic laminates using techniques such as lamination or autoclave processes. Photovoltaic laminates can be made, for example, using methods disclosed in U.S. Pat. No. 5,273,608, which is hereby incorporated herein by reference. Strip-shaped flexible photovoltaic modules are commercially available from United Solar Ovonics.

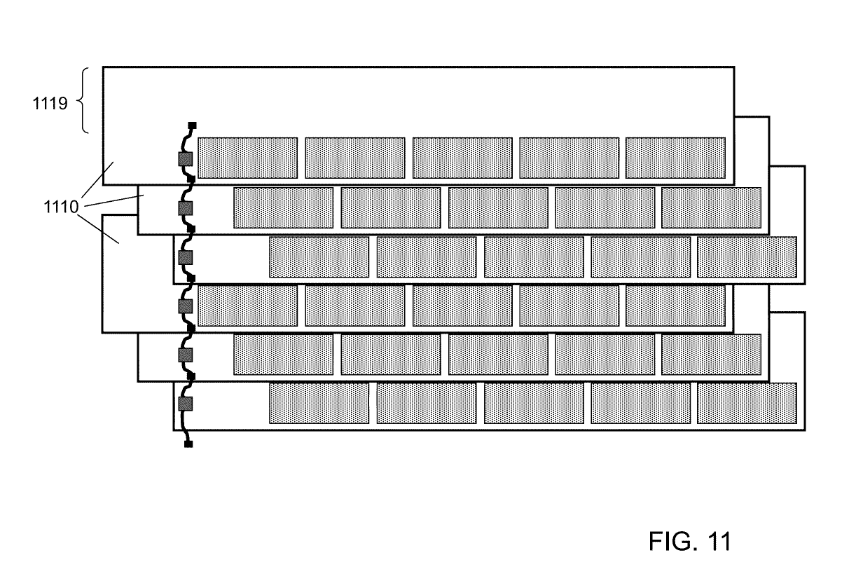

In certain embodiments, the photovoltaic module is provided as a photovoltaic roofing element, which includes one or more photovoltaic elements disposed on a roofing substrate (such as a shingle or a tile). Such photovoltaic roofing elements can be formed by the application of one or more photovoltaic elements to a roofing substrate installed on a roof, for example as described in United States Patent Application Publications nos. 2009/0159118 and 2009/0178350, each of which is incorporated herein by reference in its entirety. Alternatively, the photovoltaic roofing element can be provided as a unitary structure (i.e., assembled together with a roofing substrate to form a roofing material). An array of photovoltaic roofing elements 1110 is shown in top schematic view in FIG. 11. Photovoltaic roofing elements can include a headlap portion 1119 for closing the roof to the elements, as is conventional in the roofing arts and as disclosed in U.S. Pat. Nos. 5,575,861 and 5,437,735, each of which is hereby incorporated herein by reference in its entirety. Photovoltaic roofing elements can be formed using any of a number of types of roofing substrates. In certain embodiments, the roofing substrate is a flexible roofing substrate. For example, the roofing substrate can be an asphalt shingle, a bituminous shingle or a plastic shingle. For example, the roofing substrate can be a multilayer asphalt shingle. The manufacture of photovoltaic roofing elements using a variety of roofing substrates are described, for example, in U.S. Patent Application Publications nos. 2009/0000222, 2009/0133340, 2009/0133740, 2009/0178350 and 2009/0159118, each of which is hereby incorporated herein by reference in its entirety. As one example, in certain embodiments, the photovoltaic modules of the array are photovoltaic roofing elements each comprising a roofing substrate having at least one receptor zone, and at least one photovoltaic element disposed in each receptor zone, as described in U.S. Patent Application Publications nos. 2009/0159118 and 2009/0178350.

Individual photovoltaic cells or elements, as well as any other electrical elements (e.g., bypass diodes) within the photovoltaic module can be interconnected by wiring, for example, internal to the module.

The person of skill in the art will recognize that the electrical feature can take any of a number of forms. The electrical feature can, for example, provide any desired connectivity to the photovoltaic module. The electrical feature can be, for example, an electrical junction box, an electrical connector such as a socket or a plug, a wire emerging from the surface of the photovoltaic module (optionally connectorized for mating with wires of adjacent photovoltaic modules).

Any cabling or wiring interconnecting the photovoltaic roofing elements of the invention in a photovoltaic roofing system can, for example, be long and flexible enough to account for natural movement of a roof deck, for example due to heat, moisture and/or natural expansion/contraction. The cabling or wiring can be provided as part of a photovoltaic module, or alternatively as separate components that are interconnected with the photovoltaic modules (e.g., through electrical connectors) during installation.

Examples of electrical connectors that can be suitable for use or adapted for use in practicing various embodiments of the invention are available from Kyocera, Tyco Electronics, Berwyn, Pa. (trade name Solarlok) and Multi-Contact USA of Santa Rosa, Calif. (trade name Solarline). U.S. Pat. Nos. 7,445,508 and 7,387,537, U.S. Patent Application Publications nos. 2008/0271774, 2009/0126782, 2009/0133740, 2009/0194143 and 2010/0146878, each of which is hereby incorporated herein by reference in its entirety, disclose electrical connectors for use with photovoltaic roofing products. Of course, other suitable electrical connectors can be used. Electrical connectors desirably meet UNDERWRITERS LABORATORIES and NATIONAL ELECTRICAL CODE standards.

In certain embodiments, the photovoltaic modules of the array are electrically interconnected. The interconnected photovoltaic array can be interconnected with one or more inverters to allow photovoltaically-generated electrical power to be used on-site, stored in a battery, or introduced to an electrical grid. For example, a single inverter can be used to collect the photovoltaically-generated power and prepare it for further use. In other embodiments, the photovoltaic roofing modules can be interconnected with a plurality of micro-inverters disposed on the roof. For example, a single micro-inverter can be used for each photovoltaic module; or a single micro-inverter can be used for a group of photovoltaic modules.

Another aspect of the invention is a roof comprising a roof deck and a photovoltaic roofing array as described herein disposed on the roof deck. The photovoltaic roofing arrays described herein can be utilized with many different building structures, including residential, commercial and industrial building structures.

There can be one or more layers of material (e.g. underlayment), between the roof deck and the photovoltaic modules. The roof can also include one or more standard roofing elements, for example to provide weather protection at the edges of the roof, or in areas not suitable for photovoltaic power generation. In some embodiments, non-photovoltaically-active roofing elements are complementary in appearance or visual aesthetic to the photovoltaic roofing elements. Standard roofing elements can be interleaved at the edges of the photovoltaic arrays described herein. In certain embodiments, the photovoltaic modules are simply disposed on top of an already-installed array of standard roofing elements (e.g., an already-shingled roof).

Another aspect of the invention is a kit for the installation of a photovoltaic roofing system, the kit comprising a plurality of photovoltaic roofing elements of at least two different types as described herein. For example, in certain embodiments, a kit includes one or more first photovoltaic modules, each including a lateral edge, a set of linearly arranged features extending from that lateral edge, and an electrical element on the surface of the photovoltaic module; and one or more second photovoltaic modules, each comprising a lateral edge to be installed facing substantially the same direction as the lateral edge of the first photovoltaic module, a set of linearly arranged features extending from that lateral edge, and an electrical element on the surface of the photovoltaic module; wherein the lateral distance between the electrical element and the center of the linearly-arranged feature closest to the lateral edge is different in the first photovoltaic module than in the second. In one embodiment, the lateral distance between the electrical element and the lateral edge is substantially the same in the first photovoltaic module as in the second, as described above. In another embodiment, the sum of the distance between the electrical element and the first lateral edge of the first photovoltaic module and the electrical element and the second lateral edge of the second photovoltaic module is substantially the same as the lateral offset distance between the first photovoltaic module and the second photovoltaic module. In certain embodiments, the lateral distance between the electrical element of the first photovoltaic module and the first lateral edge of the first photovoltaic module is substantially the same as the lateral distance between the electrical element of the second photovoltaic module and the second lateral edge of the second photovoltaic module. In certain embodiments, further including a cover (e.g., a raceway or conduit) to be disposed over the electrical elements when disposed in an array in substantial lateral alignment.

Another aspect of the invention is a method for installing a photovoltaic array comprising disposing on a surface (e.g., a roof) and electrically interconnecting a plurality of photovoltaic modules as described herein. The disposal on the surface and electrical interconnections can be performed in any desirable order. The method can further include disposing a cover over substantially laterally aligned electrical elements of the photovoltaic array.

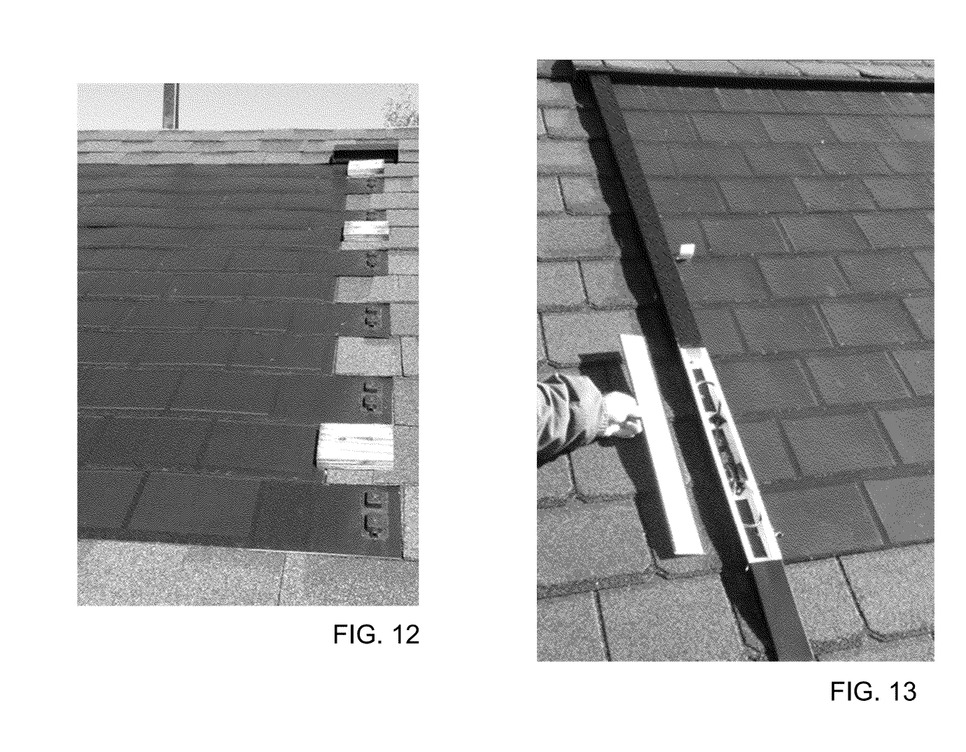

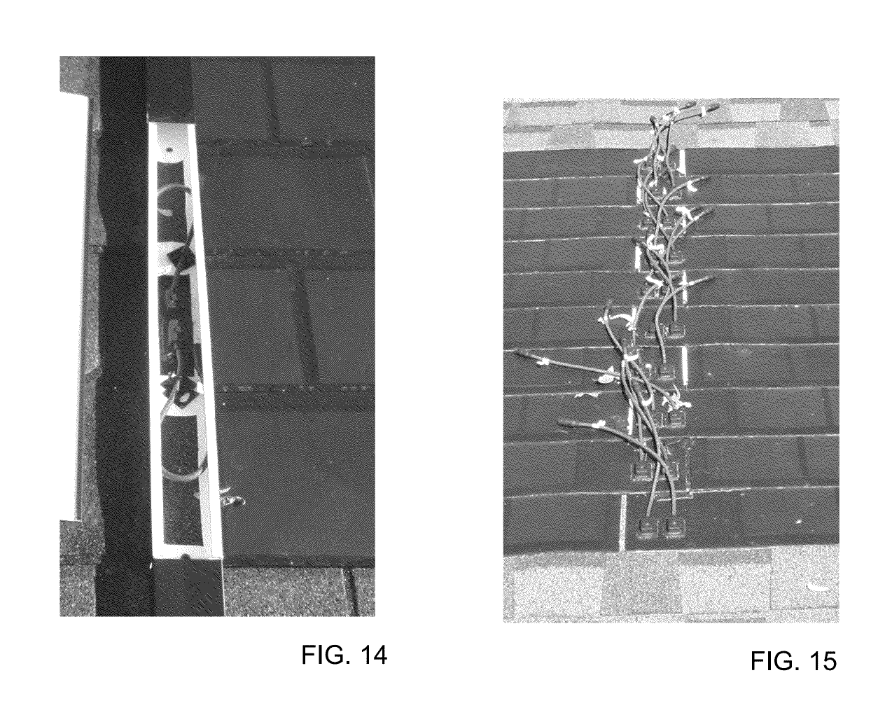

Examples of photovoltaic arrays according to various embodiments of the invention is shown in FIGS. 12-15. The photovoltaic arrays are formed from a plurality of photovoltaic laminates, generally configured as described above with respect to FIG. 8. FIG. 12 shows laterally aligned electrical elements (here, junction boxes with sockets therein) at one end of the array. FIG. 13 shows a raceway cover disposed over the electrical elements at an end of another array, with one part of the cover removed. FIG. 14 is a view of the open raceway, showing wiring interconnecting the electrical elements of the photovoltaic modules disposed within the raceway. FIG. 15 is a view of interleaved array sections, showing substantial lateral alignment of the electrical elements of the interleaved modules.

Further, the foregoing description of embodiments of the present invention has been presented for the purposes of illustration and description. It is not intended to be exhaustive or to limit the invention to the precise forms disclosed. As the person of skill in the art will recognize, many modifications and variations are possible in light of the above teaching. It will be apparent to those skilled in the art that various modifications and variations can be made to the present invention without departing from the scope of the invention. Thus, it is intended that the present invention cover the modifications and variations of this invention provided they come within the scope of the claims and their equivalents.

1. A photovoltaic array comprising
a first photovoltaic module comprising
a lateral edge,
a set of linearly arranged features extending from that lateral edge, and
an electrical element on the surface of the first photovoltaic module; and
a second photovoltaic module disposed substantially parallel to the first photovoltaic module, the second photovoltaic module comprising
a lateral edge oriented facing substantially the same direction as the lateral edge of the first photovoltaic module,
a set of linearly arranged features extending from that lateral edge, and
an electrical element on the surface of the second photovoltaic module;
wherein
the lateral edge of the second photovoltaic module is substantially laterally aligned with the lateral edge of the first photovoltaic module;
the lateral distance between the electrical element and the lateral edge is substantially the same in the first photovoltaic module as in the second photovoltaic module;
the linearly-arranged features of the second photovoltaic module are laterally offset with respect to the linearly-arranged features of the first photovoltaic module; and
the electrical element of the second photovoltaic module is substantially laterally aligned with the electrical element of the first photovoltaic module.

2. A photovoltaic array according to claim 1, wherein the linearly arranged features are individual photovoltaic elements.

3. A photovoltaic array according to claim 1, wherein the linearly arranged features of the first photovoltaic module are geometrical shapes formed in the first photovoltaic module; and the linearly arranged features of the second photovoltaic module are geometrical shapes formed in the second photovoltaic module.

4. A photovoltaic array according to claim 1, wherein the lateral offset distance between the linearly-arranged features of the second photovoltaic module and the linearly-arranged features of the first photovoltaic module is substantially the same as the difference between the lateral distance from the electrical element to the center of the linearly-arranged feature closest to the lateral edge in the first photovoltaic module and the lateral distance from the electrical element to the center of the linearly-arranged feature closest to the lateral edge in the second photovoltaic module.

5-6. (canceled)

7. The photovoltaic array according to claim 1, comprising a plurality of the first photovoltaic module and a plurality of the second photovoltaic module, arrayed in a racked configuration.

8. The photovoltaic array according to claim 1, further including a cover disposed over the electrical elements of the first photovoltaic module and the second photovoltaic module.

9. The photovoltaic array according to claim 1, wherein the first photovoltaic module and the second photovoltaic module are photovoltaic roofing elements each comprising a roofing substrate having at least one receptor zone, and at least one photovoltaic element disposed in each receptor zone.

10. The photovoltaic array according to claim 9, wherein the photovoltaic roofing elements are photovoltaic roofing modules each comprise a headlap portion.

11. The photovoltaic array according to claim 1, disposed on a roof.

12. A kit comprising
a first photovoltaic module comprising
a lateral edge,
a set of linearly arranged features extending from that lateral edge, and
an electrical element on the surface of the photovoltaic module; and
a second photovoltaic module comprising
a lateral edge,
an electrical element on the surface of the first photovoltaic module;
wherein
the lateral offset distance between the linearly-arranged features of the second photovoltaic module and the linearly-arranged features of the first photovoltaic module is substantially the same as the difference between the lateral distance from the electrical element to the center of the linearly-arranged feature closest to the lateral edge in the first photovoltaic element and the lateral distance from the electrical element to the center of the linearly-arranged feature closest to the lateral edge in the second photovoltaic element; and
the lateral distance between the electrical element and the lateral edge is substantially the same in the first photovoltaic module as in the second photovoltaic module.

13. The kit according to claim 12, wherein the linearly arranged features are individual photovoltaic elements.

14. The kit according to claim 12, wherein the linearly arranged features are geometrical shapes formed in the photovoltaic module.

15. The kit according to claim 12, wherein the lateral offset distance is substantially the same as the difference between the lateral distance from the electrical element to the center of the linearly-arranged feature closest to the lateral edge in the first photovoltaic element and the lateral distance from the electrical element to the center of the linearly-arranged feature closest to the lateral edge in the second photovoltaic element.

16.

17. The kit according to claim 12, further comprising a cover adapted to be disposed over the electrical elements of the first photovoltaic module and the second photovoltaic module when the photovoltaic modules are installed such that the electrical element of the first photovoltaic module is substantially laterally aligned with the electrical element of the second photovoltaic module, and the lateral edge of the second photovoltaic module is substantially laterally aligned with the lateral edge of the first photovoltaic module.

18. The kit according to claim 12, wherein the first photovoltaic module and the second photovoltaic module are photovoltaic roofing elements each comprising a roofing substrate having at least one receptor zone, and at least one photovoltaic element disposed in each receptor zone.

19. The kit according to claim 18, wherein the photovoltaic roofing elements each comprising a headlap portion.

20. A photovoltaic array comprising
a first photovoltaic module comprising
a first lateral edge and a second lateral edge opposite the first lateral edge,
a set of linearly arranged features extending between the first lateral edge and the second lateral edge, and
an electrical element on the surface of the first photovoltaic module; and
a second photovoltaic module disposed substantially parallel to and vertically and laterally offset with respect to the first photovoltaic module, the second photovoltaic module comprising
a first lateral edge oriented facing substantially the same direction as the first lateral edge of the first photovoltaic module, and a second lateral edge opposite the first lateral edge, the second lateral edge being oriented facing substantially the same direction as the second lateral edge of the first photovoltaic module;
a set of linearly arranged features extending between the first lateral edge and the second lateral edge, and
an electrical element on the surface of the second photovoltaic module;
wherein
the linearly-arranged features of the second photovoltaic module are laterally offset with respect to the linearly-arranged features of the first photovoltaic module;
the electrical element of the second photovoltaic module is substantially laterally aligned with the electrical element of the first photovoltaic module;
the lateral distance between the electrical element and the center of the linearly-arranged feature closest to the first lateral edge is different in the first photovoltaic module than in the second; and
the sum of the distance between the electrical element of the first photovoltaic module and the first lateral edge of the first photovoltaic module and the distance between the electrical element of the second photovoltaic module and the second lateral edge of the second photovoltaic module is substantially the same as the lateral offset distance between the linearly-arranged features of the first photovoltaic module and the linearly-arranged features of the second photovoltaic module.

21. The photovoltaic array according to claim 20, wherein the lateral distance between the electrical element of the first photovoltaic module and the first lateral edge of the first photovoltaic module is substantially the same as the lateral distance between the electrical element of the second photovoltaic module and the second lateral edge of the second photovoltaic module.

22. The photovoltaic array according to claim 20, comprising a plurality of the first photovoltaic module and a plurality of the second photovoltaic module, arrayed in a racked configuration.
